(19) United States
(12) Patent Application Publication
(10) Pub. No.: US 2023/0085460 A1
(43) Pub. Date: Mar. 16, 2023

(54) DISPLAY DEVICE

(71) Applicant: SAMSUNG DISPLAY CO., LTD., Yongin-si (KR)

(72) Inventors: Kiju Im, Yongin-si (KR); Jongwoo Park, Yongin-si (KR); Hyeokjae Kwon, Yongin-si (KR); Yoonho Kim, Yongin-si (KR); Jongyeob Kim, Yongin-si (KR); Junehwan Kim, Yongin-si (KR); Taeyoung Kim, Yongin-si (KR); Hyuncheol Hwang, Yongin-si (KR)

(21) Appl. No.: 17/703,176

(22) Filed: Mar. 24, 2022

(30) Foreign Application Priority Data
Sep. 14, 2021 (KR) 10-2021-0122768

(51) Int. Cl. H01L 27/32; H01L 51/52

(52) U.S. Cl. CPC H01L 27/3262; H01L 51/5284

(57) ABSTRACT

A display device includes a display panel and a metal plate disposed under the display panel, where the metal plate includes a first area and a second area which is adjacent to the first area, and a plurality of through holes is defined through the metal plate. The plurality of through holes includes a first through hole and a second through hole, which are spaced apart from each other at a first interval in the first area, and a third through hole and a fourth through hole, which are spaced apart from each other at a second interval in the second area, and the first interval is different from the second interval.

This application claims priority to Korean Patent Application No. 10-2021-0122768, filed on Sep. 14, 2021, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

With the development of the information society, the demand for display devices for displaying images has increased in various fields. A display device may be used as a display of a small product such as a cell phone, a display of a product such as a tablet personal computer (“PC”) or a laptop, or a display of a large-sized product such as a television (“TV”).

Such a display device may be used for a long period of time.

### SUMMARY

One or more embodiments provide a display device capable of displaying an image without stains even though the display device is used for a long period of time.

According to one or more embodiments, a display device includes a display panel and a metal plate disposed under the display panel, where the metal plate includes a first area and a second area which is adjacent to the first area, and a plurality of through holes is defined through the metal plate, where the plurality of through holes include a first through hole and a second through hole, which are spaced apart from each other at a first interval in the first area, and a third through hole and a fourth through hole, which are spaced apart from each other at a second interval in the second area, and the first interval is different from the second interval.

In an embodiment, the first area may overlap the center of the metal plate, and the first interval may be less than the second interval.

In an embodiment, the second area may surround at least a portion of the first area.

In an embodiment, the second area may entirely surround the first area.

In an embodiment, an interval between adjacent through holes from among the plurality of through holes may be less than or equal to about 2 mm.

In an embodiment, a size of one of the plurality of through holes may be less than or equal to about 0.5 millimeter (mm).

In an embodiment, a planar shape of one of the plurality of through holes may be one of a circle and a polygon.

In an embodiment, the display panel may include a substrate including a display area, a pixel circuit layer disposed on the substrate, where the pixel circuit may include a pixel circuit overlapping the display area, and a display element layer disposed on the pixel circuit layer, where the display element may include a display element, where the pixel circuit may include a driving thin film transistor and a switching thin film transistor, and the plurality of through holes may overlap the display area.

In an embodiment, the display device may further include an adhesive layer disposed between the display panel and the metal plate, and a plurality of openings overlapping the plurality of through holes may be defined through the adhesive layer.

In an embodiment, the display device may further include a protective layer disposed between the display panel and the adhesive layer and overlapping the plurality of through holes, and a graphite sheet disposed under the metal plate and overlapping the plurality of through holes.

According to one or more embodiments, a display device includes a display panel, an adhesive layer disposed under the display panel, where a plurality of openings is defined through the adhesive layer, and a graphite sheet disposed under the metal plate and overlapping the plurality of through holes.

In an embodiment, the metal plate may include a first area and a second area which is adjacent to the first area, the plurality of through holes may include a first through hole and a second through hole, which are spaced apart from each other at a first interval in the first area, and a third through hole and a fourth through hole, which are spaced apart from each other at a second interval in the second area, and the first interval may be different from the second interval.

In an embodiment, the first area may overlap a center of the metal plate, and the first interval may be less than the second interval.

In an embodiment, the second area may surround at least a portion of the first area.

In an embodiment, the second area may entirely surround the first area.

In an embodiment, an interval between adjacent through holes from among the plurality of through holes may be less than or equal to about 2 mm.

In an embodiment, a size of one of the plurality of through holes may be less than or equal to about 0.5 mm.

In an embodiment, a planar shape of one of the plurality of through holes may be one of a circle and a polygon.

In an embodiment, the display panel may include a substrate including a display area, a pixel circuit layer disposed on the substrate, where the pixel circuit layer may include a pixel circuit overlapping the display area, and a display element layer disposed on the pixel circuit layer, where the display element may include a display element, where the pixel circuit may include a driving thin film transistor and a switching thin film transistor, and the plurality of through holes may overlap the display area.

In an embodiment, the display device may further include a protective layer disposed between the display panel and the adhesive layer and overlapping the plurality of through holes, and a reflection prevention layer disposed on the display panel.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display device according to an embodiment;

FIGS. 2A and 2B are schematic cross-sectional views of a display device according to various embodiments, taken along line A-A′ of FIG. 1;

FIG. 3 is a schematic plan view of a display panel according to an embodiment;

FIG. 4 is a schematic equivalent circuit diagram of one of pixels in a display panel, according to an embodiment;

FIG. 5 is a schematic cross-sectional view of the display panel of FIG. 3, taken along line B-B′ of FIG. 3;

FIG. 6 is a schematic plan view of a metal plate according to an embodiment;

FIG. 7 is a view of an enlarged region C of the metal plate of FIG. 6, according to an embodiment;

FIG. 8A is a diagram of a metal plate including a through hole;

FIG. 8B is a diagram illustrating stains on a display device including a metal plate and a display panel, when the display device operates for a long period of time in a high-temperature and high-humidity state;

FIGS. 9A to 9C are diagrams of an enlarged region C of the metal plate of FIG. 6, according to various embodiments; and

FIGS. 10A and 10B are schematic plan views of a metal plate according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art

Hereinafter, the invention will be described in detail by explaining preferred embodiments of the invention with reference to the attached drawings. Like reference numerals in the drawings denote like elements, and thus their description will be omitted.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or component is referred to as being “on” another layer, region, or component, it can be directly or indirectly on the other layer, region, or component. That is, for example, intervening layers, regions, or components may be present. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly and/or indirectly connected to the other layer, region, or component. That is, for example, intervening layers, regions, or components may be present. It will be understood that when a layer, region, or component is referred to as being electrically connected to another layer, region, or component, it can be electrically and directly and/or indirectly connected to the other layer, region, or component. That is, for example, intervening layers, regions, or components may be present.

Hereinafter, embodiments of the in invention will be described in detail with reference to the accompanying drawings.

In embodiments, a display device displays a moving image or a still image and may be used as a display screen of various products, for example, a portable electronic device such as a mobile phone, a smartphone, a tablet personal computer (“PC”), a mobile communication terminal, a personal digital assistant, an e-book terminal, a portable multimedia player (“PMP”), a navigation device, or an ultra mobile PC (“UMPC”), a television (“TV”), a laptop, a monitor, a billboard, an internet of things (“IoT”) device, and the like. Also, the display device according to an embodiment may be used in a wearable device such as a smartwatch, a watch phone, an eyewear display, or a head mounted display (“HMD”). Also, the display device may be used as a display in an instrument cluster of a vehicle, a center information display (“CID”) mounted on a center fascia or a dashboard of a vehicle, a room mirror display replacing a side-view mirror of a vehicle, or a car headrest monitor provided for rear-seat entertainment.

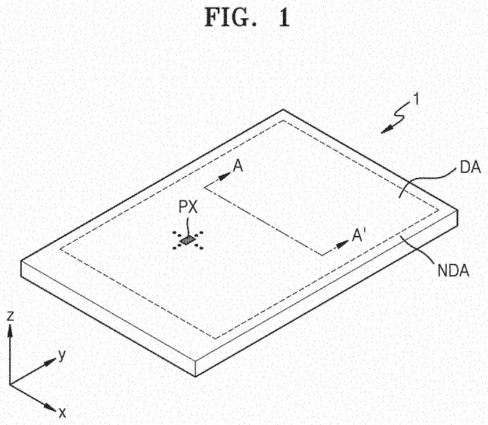

FIG. 1 is a schematic perspective view of a display device 1 according to an embodiment.

Referring to FIG. 1, an embodiment of the display device 1 may display an image. The display device 1 may include a display area DA and a non-display area NDA. In the display area DA, a pixel PX may be arranged or disposed. The non-display area NDA may surround at least a portion of the display area DA. In the non-display area NDA, the pixel PX may not be arranged.

FIG. 1 illustrates an embodiment where the display device 1 has a rectangular display area DA, but not being limited thereto. In an alternative embodiment, the shape of the display area DA may be a circle, an oval, or a polygon such as a triangle or a pentagon. Also, FIG. 1 illustrates an embodiment where the display device 1 is a flat display device having a flat state, but not being limited thereto. Alternatively, the display device 1 may be realized in various forms such as a flexible, foldable, or rollable display device.

The pixel PX may be provided in plural. The pixels PX may be arranged in the display area DA. The pixels PX may emit light, and the display device 1 may display an image in the display area DA. In an embodiment, any one of the pixels PX may emit red light, green light, or blue light. In an alternative embodiment, any one of the pixels PX may emit red light, green light, blue light, or white light.

The pixel PX may include a display element. In an embodiment, the display element may be an organic light-emitting diode including an organic emission layer. Alternatively, the display element may be a light-emitting diode (“LED”) including an inorganic emission layer. A size of the LED may be a micro-scale or a nano-scale. In an embodiment, for example, the LED may be a micro-LED. Alternatively, the LED may be a nanorod LED. The nanorod LED may include gallium nitride (GaN). In an embodiment, a color conversion layer may be arranged on the nanorod LED. The color conversion layer may include quantum dots. Alternatively, the display element may be a quantum dot light-emitting diode including a quantum dot emission layer. Hereinafter, for convenience of description, embodiments where the display element is an organic light-emitting diode will be described in detail.

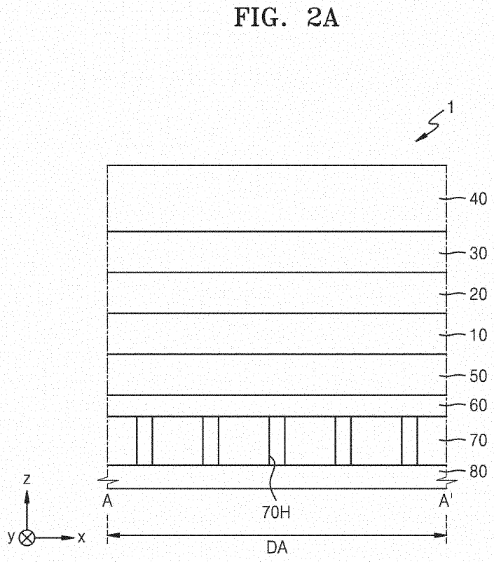

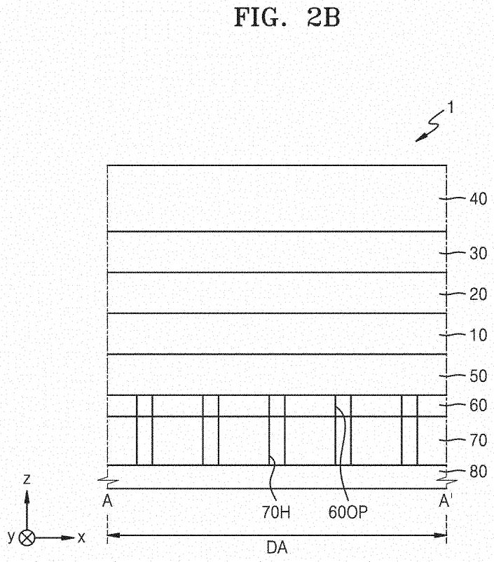

FIGS. 2A and 2B are schematic cross-sectional views of the display device 1 according to various embodiments, taken along line A-A′ of FIG. 1. The same reference symbols in FIGS. 2A to 2B denote the same elements as those in FIG. 1, and any repetitive detailed descriptions thereof will be omitted.

Referring to FIGS. 2A and 2B, an embodiment of the display device 1 may include a display panel 10, a reflection prevention layer 20, a window adhesive layer 30, a cover window 40, a protective layer 50, an adhesive layer 60, a metal plate 70, and a graphite sheet 80.

The display panel 10 may display an image. The display panel 10 may include a substrate, a pixel circuit layer including a pixel circuit, and a display element layer including a display element driven by the pixel circuit. In an embodiment, the display panel 10 may further include an encapsulation layer, which encapsulates the display element layer, and a touch sensor layer, which detects a touch.

The reflection prevention layer 20 may be on the display panel 10. The reflection prevention layer 20 may decrease the reflectivity of light that is incident to the display panel 10. In an embodiment, the reflection prevention layer 20 may include a retarder and/or a polarizer. The retarder may be of a film type or a liquid crystal coating type and may include a λ/2 retarder and/or a λ/4 retarder. The polarizer may also be of a film type or a liquid crystal coating type. The polarizer of the film type may include a stretched synthetic resin film, and the polarizer of the liquid crystal coating type may include liquid crystals arranged in a certain arrangement. The retarder and the polarizer may further include a protective film.

In an alternative embodiment, the reflection prevention layer 20 may include a black matrix and color filters. The color filters may be arranged considering colors of light emitted from the display element of the display panel 10. Each color filter may include a red, green, or blue pigment or dye. Alternatively, each color filter may further include quantum dots in addition to the above pigment or dye. Alternatively, some of the color filters may not include the above pigment or dye and may include scattered particles such as titanium oxide.

In another alternative embodiment, the reflection prevention layer 20 may include a destructive interference structure. In such an embodiment, the destructive interference structure may include a first reflection layer and a second reflection layer that are on different layers. First reflection light and second reflection light, which are respectively reflected from the first reflection layer and the second reflection layer, may destructively interfere with each other, and the external light reflectivity may decrease accordingly.

The window adhesive layer 30 may be on the reflection prevention layer 20. The window adhesive layer 30 may attach the reflection prevention layer 20 to the cover window 40. In an embodiment, the window adhesive layer 30 may be an optically clear adhesive. In an embodiment, the window adhesive layer 30 may be a pressure sensitive adhesive.

The cover window 40 may be arranged (or disposed) on the window adhesive layer 30. The cover window 40 may protect the display panel 10. In an embodiment, the cover window 40 may include glass. In an embodiment, the cover window 40 may be a flexible window. The cover window 40 may be easily bent by an external impact without the appearance of cracks and may protect the display panel 10. In an embodiment, the cover window 40 may include ultra-thin glass or colorless polyimide. In an embodiment, the cover window 40 may include a structure in which a flexible polymer layer is arranged on a surface of a glass substrate or a structure including only a polymer layer.

The protective layer 50 may be arranged under the display panel 10. In such an embodiment, the display panel 10 may be arranged between the reflection prevention layer 20 and the protective layer 50. The protective layer 50 may include polymer resin. In an embodiment, for example, the polymer resin may include at least one selected from polyethersulfone, polyacrylate, polyetherimide, polyethylene naphthalate, polyethylene terephthalate, polyphenylene sulfide, polyimide, polycarbonate, and cellulose acetate propionate. In another embodiment, the protective layer 50 may include an inorganic material. In an embodiment, for example, the protective layer 50 may include a material such as glass or quartz.

The adhesive layer 60 may be under the protective layer 50. In an embodiment, the adhesive layer 60 may be an optically clear adhesive. In an embodiment, the adhesive layer 60 may be a pressure sensitive adhesive.

The metal plate 70 may be under the adhesive layer 60. The adhesive layer 60 may be arranged between the display panel 10 and the metal plate 70. In an embodiment, the metal plate 70 may be under the display panel 10. In an embodiment, the metal plate 70 may deliver, to the outside, heat generated from the display device 1. In such an embodiment, the metal plate 70 may support the display panel 10. The metal plate 70 may maintain the flatness of the display panel 10. The metal plate 70 may include at least one selected from copper, nickel, ferrite, and silver that have great thermal conductivity.

The metal plate 70 may include a plurality of through holes 70H, that is, the plurality of through holes 70H may be defined through the metal palate 70. The plurality of through holes 70H may extend from an upper surface of the metal plate 70, which faces the display panel 10, to a lower surface of the metal plate 70, which is opposite to the upper surface of the metal plate 70. In an embodiment, the lower surface of the metal plate 70 may face the graphite sheet 80. In an embodiment, the plurality of through holes 70H may overlap the display area DA. In an embodiment, the plurality of through holes 70H may overlap the protective layer 50. In an embodiment, for example, the protective layer 50 may continuously extend in the display area DA, and the protective layer 50 may be arranged above the plurality of through holes 70H.

FIGS. 2A and 2B illustrate an embodiment where the plurality of through holes 70H are arranged at regular intervals, but not being limited thereto. In an alternative embodiment, the plurality of through holes 70H may be arranged at irregular intervals. In an embodiment, for example, intervals between the plurality of through holes 70H, which are adjacent to each other in an intermediate area of the display area DA, may be less than intervals between the plurality of through holes 70H, which are adjacent to each other in an outer area located outside the intermediate area. The plurality of through holes 70H may be included in the metal plate 70 to enable the display device 1 to display an image without stains, which will be described below.

Referring to FIG. 2A, the plurality of through holes 70H may overlap the adhesive layer 60. In an embodiment, for example, the adhesive layer 60 may continuously extend in the display area DA. Therefore, the adhesive layer 60 may be on the plurality of through holes 70H.

Referring to FIG. 2B, the adhesive layer 60 may include openings 600P, that is the openings 60P may be defined through the adhesive layer 60. The openings 600P may extend from a lower surface of the adhesive layer 60, which faces the metal plate 70, to an upper surface of the adhesive layer 60, which faces the display panel 10. In an embodiment, the plurality of openings 600P may overlap the plurality of through holes 70H. Therefore, the plurality of through holes 70H and the plurality of openings 600P may be connected to each other. Similarly to the plurality of through holes 70H, the plurality of openings 600P may be included in the adhesive layer 60 to enable the display device 1 to display an image without stains.

Referring to FIGS. 2A and 2B, the graphite sheet 80 may be under the metal plate 70. In an embodiment, the metal plate 70 may be between the adhesive layer 60 and the graphite sheet 80. The graphite sheet 80 may include graphite. In an embodiment, the graphite sheet 80 may continuously extend in the display area DA. The graphite sheet 80 may overlap the plurality of through holes 70H. In such an embodiment, the graphite sheet 80 may be arranged under the plurality of through holes 70H. The graphite sheet 80 may discharge, to the outside, heat generated from the display device 1.

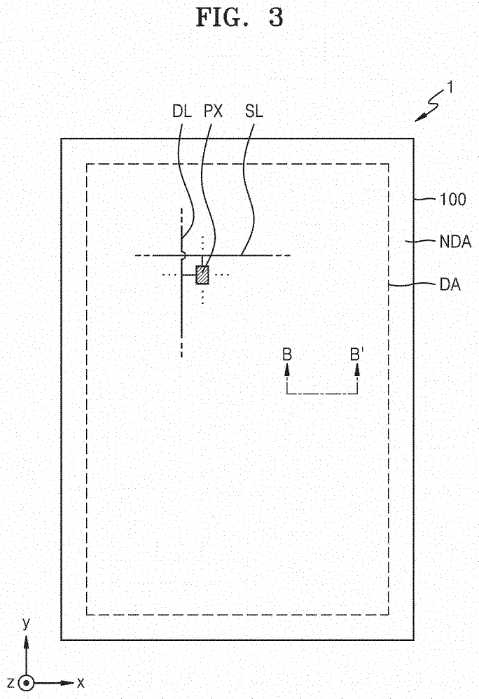

FIG. 3 is a schematic plan view of a display panel 10 according to an embodiment.

Referring to FIG. 3, an embodiment of the display panel 10 may include a substrate 100, a pixel PX, a scan line SL, and a data line DL. The display panel 10 may include the display area DA and the non-display area NDA. In an embodiment, the display area DA and the non-display area NDA may be defined in the substrate 100. In other words, the substrate 100 may include the display area DA and the non-display area NDA. The pixel PX may be arranged in the display area DA. In the non-display area NDA, a driving circuit, a power line, and/or the like of the display panel 10 may be arranged.

The pixel PX may emit light. In an embodiment, the pixel PX may be provided in plural, and the display panel 10 may display an image by using light emitted from the plurality of pixels PX. The pixel PX may be electrically connected to the scan line SL, which is configured to transmit a scan signal, and a data line DL, which is configured to transmit a data signal. The pixel PX may emit light in response to the scan signal and the data signal.

The scan line SL may be configured to transmit a scan signal. In an embodiment, the scan line SL may extend in a first direction (e.g., an x direction or a −x direction). The scan line SL may be electrically connected to the pixel PX. In an embodiment, the scan line SL may be configured to receive a scan signal from a driving circuit (not illustrated).

The data line DL may be configured to transmit a data signal. In an embodiment, the data line DL may extend in a second direction (e.g., a y direction or a −y direction). The data line DL may be electrically connected to the pixel PX. Here, z direction may be a direction perpendicular to the x direction and the y direction, or a thickness direction of the display panel 10.

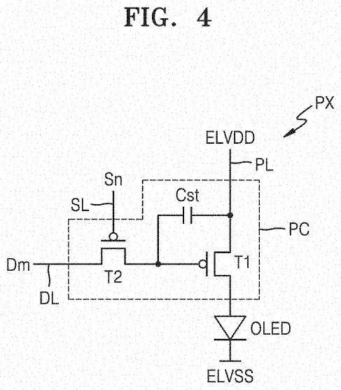

FIG. 4 is an equivalent circuit diagram of one of the pixels PX in a display panel, according to an embodiment.

Referring to FIG. 4, an embodiment of the pixel PX may include a pixel circuit PC and an organic light-emitting diode OLED that is a display element electrically connected to the pixel circuit PC. The pixel circuit PC may include a driving thin film transistor T1, a switching thin film transistor T2, and a storage capacitor Cst.

The switching thin film transistor T2 may be connected to the scan line SL and the data line DL and configured to transmit a data signal Dm, which is input through the data line DL, to the driving thin film transistor T1 in response to a scan signal Sn that is input through the scan line SL.

The storage capacitor Cst may be connected to the switching thin film transistor T2 and the driving power line PL and may store a voltage corresponding to a difference between a voltage received from the switching thin film transistor T2 and a first power voltage ELVDD provided to the driving power line PL.

The driving thin film transistor T1 may be connected to the driving power line PL and the storage capacitor Cst and control a driving current flowing in the organic light-emitting diode OLED from the driving power line PL based on the voltage stored in the storage capacitor Cst. The organic light-emitting diode OLED may emit light having certain brightness corresponding to the driving current. An opposite electrode (e.g., a cathode) of the organic light-emitting diode OLED may be configured to receive a second power voltage ELVSS.

FIG. 4 illustrates an embodiment where the pixel circuit PC includes two thin film transistors and one storage capacitor, but not being limited thereto. In an alternative embodiment, the pixel circuit PC may include three or more thin film transistors.

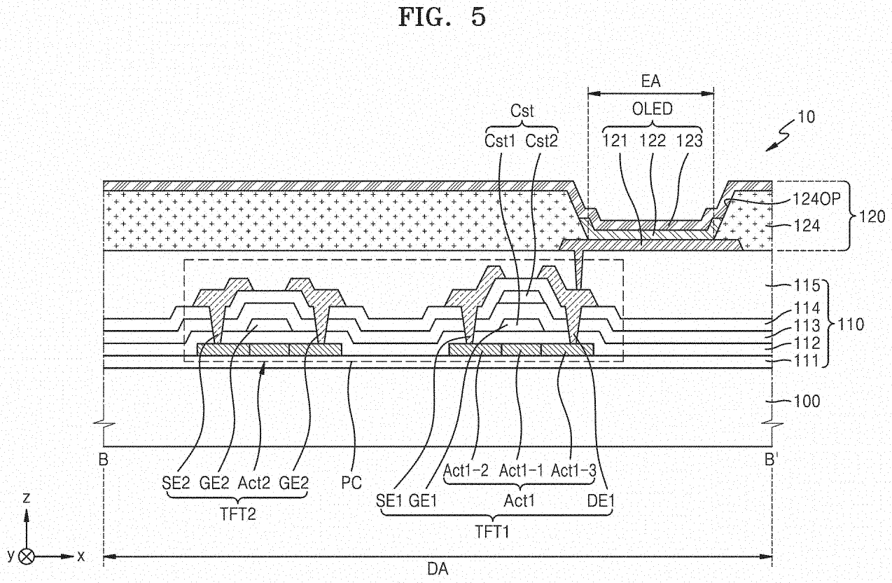

FIG. 5 is a schematic cross-sectional view of the display panel 10 of FIG. 3, taken along line B-B′ of FIG. 3.

Referring to FIG. 5, an embodiment of the display panel 10 may include the substrate 100, a pixel circuit layer 110, and a display element layer 120. The pixel circuit layer 110 and the display element layer 120 may be sequentially arranged on the substrate 100.

The substrate 100 may include the display area DA. In an embodiment, the substrate 100 may include glass. In an alternative embodiment, the substrate 100 may include polymer resin such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may have a multi-layer structure including a base layer and a barrier layer (not illustrated) including at least one selected from the aforementioned polymer resins.

The barrier layer (not illustrated) may be further arranged between the pixel circuit layer 110 and the substrate 100. The barrier layer may be a layer for preventing the penetration of external foreign materials and may have a single layer structure or a multi-layer structure, each layer therein including an inorganic material such as silicon nitride (SiNₓ) or silicon oxide (SiO₂).

The pixel circuit layer 110 may be on the substrate 100. The pixel circuit layer 110 may include the pixel circuit PC and a buffer layer 111, a first inorganic insulating layer 112, a second inorganic insulating layer 113, a third inorganic insulating layer 114, and an organic insulating layer 115 arranged under and/or on the pixel circuit PC. The pixel circuit PC may overlap the display area DA. In an embodiment, the pixel circuit PC may include a first thin film transistor TFT1, a second thin film transistor TFT2, and the storage capacitor Cst. In an embodiment, the first thin film transistor TFT1 may be a driving thin film transistor. The second thin film transistor TFT2 may be a switching thin film transistor.

The buffer layer 111 may be on the substrate 100. The buffer layer 111 may include an inorganic insulating material such as SiN_{X}, silicon oxynitride (SiON), or SiO₂ and may have a single layer structure or a multi-layer structure, each layer therein including at least one selected from the above inorganic insulating materials.

The first thin film transistor TFT1 may include a first semiconductor layer Act1, a first gate electrode GE1, a first source electrode SE1, and a first drain electrode DE1. The second thin film transistor TFT2 may include a second semiconductor layer Act2, a second gate electrode GE2, a second source electrode SE2, and a second drain electrode DE2. The second semiconductor layer Act2, the second gate electrode GE2, the second source electrode SE2, and the second drain electrode DE2 may be similar to the first semiconductor layer Act1, the first gate electrode GE1, the first source electrode SE1, and the first drain electrode DE1, respectively. Thus, detailed descriptions thereof will be omitted.

The first semiconductor layer Act1 may be on the buffer layer 111. The first semiconductor layer Act1 may include polysilicon. Alternatively, the first semiconductor layer Act1 may include amorphous silicon, an oxide semiconductor, an organic semiconductor, or the like. In an embodiment, the first semiconductor layer Act1 may include a channel area Act1-1 and source and drain areas Act1-2 and Act1-3 on both sides of the channel area Act1-1.

The first gate electrode GE1 may overlap the channel area Act1-1 of the first semiconductor layer Act1. The first gate electrode GE1 may include a low-resistance metal material. The first gate electrode GE1 may include a conductive material such as molybdenum (Mo), aluminum (Al), copper (Cu), or titanium (Ti) and may have a single layer structure or a multi-layer structure, each layer therein including at least one selected from the above materials.

The first inorganic insulating layer 112 may be between the first semiconductor layer Act1 and the first gate electrode GE1. The first inorganic insulating layer 112 may include an inorganic insulating material such as SiO₂, SiN_{X}, SiON, aluminum oxide (Al₂O₃), titanium oxide (TiO₂), tantalum oxide (Ta₂O₅), hafnium oxide (HfO₂), or zinc oxide (ZnOₓ). ZnOₓ may include zinc oxide (ZnO) and/or zinc peroxide (ZnO₂).

The second inorganic insulating layer 113 may cover the first gate electrode GE1. Similarly to the first inorganic insulating layer 112, the second inorganic insulating layer 113 may include an inorganic insulating material such as SiO₂, SiNₓ, SiON, Al₂O₃, TiO₂, Ta₂O₅, HfO₂, or ZnOₓ.

An upper electrode Cst2 of the storage capacitor Cst may be arranged on the second inorganic insulating layer 113. In an embodiment, the upper electrode Cst2 may overlap the first gate electrode GE1. In such an embodiment, the first gate electrode GE1 and the upper electrode Cst2, which overlap each other with the second inorganic insulating layer 113 therebetween, may constitute the storage capacitor Cst. In such an embodiment, the first gate electrode GE1 may function as a lower electrode Cst1 of the storage capacitor Cst. In an embodiment, as described, the storage capacitor Cst and the first thin film transistor TFT1 may overlap each other. In an alternative embodiment, the storage capacitor Cst and the first thin film transistor TFT1 may not overlap each other. In an embodiment, the storage capacitor Cst and the second thin film transistor TFT2 may not overlap each other. The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu and have a single layer structure or a multi-layer structure, each layer therein including at least one selected from the above materials.

The third inorganic insulating layer 114 may cover the upper electrode Cst2. The third inorganic insulating layer 114 may include SiO₂, SiN_{X}, SiON, Al₂O₃, TiO₂, Ta₂O₅, HfO₂, or ZnOₓ. The third inorganic insulating layer 114 may have a single layer structure or a multi-layer structure, each layer therein including at least one selected from the above inorganic insulating materials.

The first source electrode SE1 and the first drain electrode DE1 may be on the third inorganic insulating layer 114, respectively. At least one selected from the first source electrode SE1 and the first drain electrode DE1 may include a material having high conductivity. At least one selected from the first source electrode SE1 and the first drain electrode DE1 may include a conductive material such as Mo, Al, Cu, or Ti and may have a single layer structure or a multi-layer structure, each layer therein including at least one selected from the above materials. In an embodiment, at least one selected from the first source electrode SE1 and the first drain electrode DE1 may have a multi-layer structure of Ti/Al/Ti.

The organic insulating layer 115 may be on the third inorganic insulating layer 114, the first source electrode SE1, the second source electrode SE2, the first drain electrode DE1, and the second drain electrode DE2. The organic insulating layer 115 may include organic insulating materials such as a general-purpose polymer such as polymethylmethacrylate (“PMMA”) or polystyrene (“PS”), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any blend thereof.

The display element layer 120 may be on the pixel circuit layer 110. The display element layer 120 may include the organic light-emitting diode OLED that is a display element, and a pixel-defining layer 124. The organic light-emitting diode OLED may emit, for example, red, green, or blue light or may emit red, green, blue, or white light. In an embodiment, the organic light-emitting diode OLED as a display element may be on the organic insulating layer 115. The organic light-emitting diode OLED may include a pixel electrode 121, an emission layer 122, and an opposite electrode 123.

The pixel electrode 121 may be on the organic insulating layer 115. The pixel electrode 121 may be electrically connected to the first thin film transistor TFT1 through a contact hole of the organic insulating layer 115. The pixel electrode 121 may include conductive oxide such as indium tin oxide (“ITO”), indium zinc oxide (“IZO”), ZnO, indium oxide (In₂O₃), indium gallium oxide (“IGO”), or aluminum zinc oxide (“AZO”). In another embodiment, the pixel electrode 121 may include a reflection layer including Ag, Mg, Al, Pt, Pd, Au, Ni, Nd, Ir, Cr, or a compound thereof. In an alternative embodiment, the pixel electrode 121 may further include a layer including ITO, IZO, ZnO, or In₂O₃ on/under the reflection layer.

In an embodiment, a pixel-defining layer 124 including an opening 1240P, through which a central portion of the pixel electrode 121 is exposed, may be arranged on the pixel electrode 121. The pixel-defining layer 124 may include an organic insulating material and/or an inorganic insulating material. In an embodiment, the pixel-defining layer 124 may include a light-shielding material. The opening 1240P may define an emission area EA of light emitted from the organic light-emitting diode OLED. In an embodiment, for example, a width of the opening 1240P may be that of the emission area EA.

The emission layer 122 may be arranged in the opening 1240P of the pixel-defining layer 124. The emission layer 122 may include a polymer or low-molecular-weight organic material emitting a certain color of light. Although not illustrated, a first functional layer and a second functional layer may be arranged under and on the emission layer 122. The first functional layer may include, for example, a hole transport layer (“HTL”) or may include an HTL and a hole injection layer (“HIL”). The second functional layer may be an element on the emission layer 122 and may be optional. The second functional layer may include an electron transport layer (“ETL”) and/or an electron injection layer (“EIL”). The first functional layer and/or the second functional layer may be common layers formed to entirely cover the substrate 100 like the opposite electrode 123 described below.

The opposite electrode 123 may be on the emission layer 122 and the pixel-defining layer 124. The opposite electrode 123 may include a conductive material having a low work function. In an embodiment, for example, the opposite electrode 123 may include a transparent (translucent) layer including Ag, Mg, Al, Pt, Pd, Au, Ni, Nd, Ir, Cr, lithium (Li), Ca, or an alloy thereof. Alternatively, the opposite electrode 123 may further include a layer including ITO, IZO, ZnO, or In₂O₃ on the transparent (translucent) layer including at least one selected from the above materials.

Although not illustrated, an encapsulation layer may be arranged on the display element layer 120. The encapsulation layer may include at least one inorganic encapsulation layer and at least one organic encapsulation layer that cover the display element layer 120. In an embodiment, at least one inorganic encapsulation layer and at least one organic encapsulation layer may be alternately stacked one on another. The inorganic encapsulation layer may include at least one inorganic materials selected from Al₂O₃, TiO₂, Ta₂O₅, ZnOₓ, SiO₂, SiN_{X}, and SiON. The organic encapsulation layer may include a polymer-based material. The polymer-based material may include at least one selected from acryl-based resin, epoxy-based resin, polyimide, and polyethylene. In an embodiment, the organic encapsulation layer may include acrylate.

In an alternative embodiment, a sealing substrate may be arranged on the display element layer 120. The sealing substrate may seal the display element layer 120 together with a sealing member arranged in the non-display area. In another alternative embodiment, the encapsulation layer and the sealing substrate may be simultaneously arranged on the display element layer 120.

A touch sensor layer may be arranged on the encapsulation layer. The touch sensor layer may obtain coordinate information corresponding to an external input, for example, a touch event.

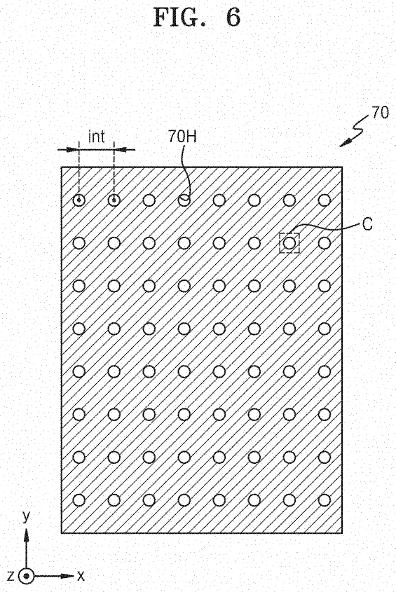

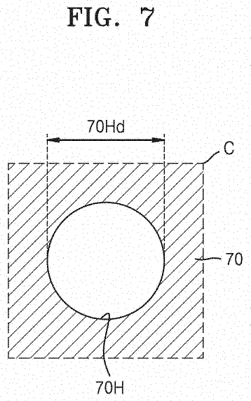

FIG. 6 is a schematic plan view of the metal plate 70 according to an embodiment. FIG. 7 is a view of an enlarged region C of the metal plate 70 of FIG. 6, according to an embodiment.

Referring to FIGS. 6 and 7, an embodiment of the metal plate 70 may include the plurality of though holes 70H, that is, the plurality of through holes 70H may be defined through the metal plate 70. The plurality of through holes 70H may extend through the metal plate 70. The plurality of through holes 70H may be arranged in the first direction (e.g., the x direction or −x direction) and/or the second direction (e.g., the y direction or the −y direction). In an embodiment, the plurality of through holes 70H may be arranged at regular intervals in the first direction (e.g., the x direction or −x direction) and/or the second direction (e.g., the y direction or the −y direction). In an alternative embodiment, the plurality of through holes 70H may be arranged at irregular intervals in the first direction (e.g., the x direction or −x direction) and/or the second direction (e.g., the y direction or the −y direction).

A planar shape of a through hole 70H may be one of a circle or a polygon. The planar shape may be a shape of the through hole 70H in a plan view. In an embodiment, the planar shape of the through hole 70H may be a circle. In an alternative embodiment, the planar shape of the through hole 70H may be a polygon. In another alternative embodiment, the planar shape of the through hole 70H may be one of other various shapes.

When a display device is used for a long period of time, moisture may permeate into the metal plate 70. The moisture may not permeate into a pixel circuit or a display element layer of a display panel and thus may not affect the lifetime of the pixel circuit or the display element. However, the moisture may permeate into the inside of the metal plate 70. In this case, light reflected from the metal plate 70 may affect a substrate including an organic material and/or a pixel circuit. In an embodiment, for example, the light may affect a driving thin film transistor.

In a case where the metal plate 70 does not include the plurality of through holes 70H unlike the embodiment described herein, the moisture may not evenly permeate into the inside of the metal plate 70. In this case, a relatively great amount of moisture may permeate into edges of the metal plate 70, and a relatively small amount of moisture may permeate into the center of the metal plate 70. In this case, when external light is incident to the metal plate 70, the first light reflectivity in a permeated area of the metal plate 70, where moisture permeates, may be different from the second light reflectivity in a non-permeated area of the metal plate 70, where moisture does not permeate. The first light reflectivity and the second light reflectivity may affect a first substrate area of the substrate, which overlaps the permeated area, and a second substrate area of the substrate, which overlaps the non-permeated area. Also, the first light reflectivity and the second light reflectivity may affect a driving thin film transistor of a first pixel circuit, which overlaps the permeated area, and a driving thin film transistor of a second pixel circuit, which overlaps the non-permeated area. In this case, because the first light reflectivity is different from the second light reflectivity, components or characteristics of the substrate may differ in the first substrate area and the second substrate area. Also, because the first light reflectivity is different from the second light reflectivity, the amount of light reaching the driving thin film transistor of the first pixel circuit and the driving thin film transistor of the second pixel circuit may vary. Also, a difference between the components of the substrate in the first substrate area and the second substrate area may affect the driving thin film transistor of the first pixel circuit and the driving thin film transistor of the second pixel circuit. Therefore, although the same signal is transmitted to the driving thin film transistor of the first pixel circuit, which overlaps the permeated area, and the driving thin film transistor of the second pixel circuit, which overlaps the non-permeated area, the driving thin film transistors of the first and second pixel circuits may operate differently, which causes stains on the display device.

In an embodiment of the invention, the moisture may permeate into the inside of the metal plate 70 through the plurality of through holes 70H. Therefore, the moisture may permeate into the entire metal plate 70, and the driving thin film transistors of the pixel circuits of the display panel, to which the same signal is transmitted, may operate in a same manner. Therefore, the plurality of through holes 70H may prevent or decrease the stains on the display device.

An interval int between adjacent through holes 70H among the plurality of through holes 70H may be less than or equal to about 2 millimeters (mm). The interval int between adjacent through holes 70H may be a distance between the center of a first through hole and the center of the second through hole that is adjacent to the first through hole. Therefore, the moisture may entirely permeate into the metal plate 70.

A size 70Hd of one of the plurality of through holes 70H may be less than or equal to about 0.5 mm. In an embodiment, the sizes 70Hd of the plurality of through holes 70H may all be less than or equal to about 0.5 mm. The size 70Hd of the through hole 70H may be a maximum width thereof. In an embodiment, for example, on a plan view, when the through hole 70H has a circular shape, the size 70Hd of the through hole 70H may be a diameter of the through hole 70H. If the size 70Hd of the through hole 70H is greater than about 0.5 mm, the display panel 10 on the metal plate 70 may be curved because of the through hole 70H. In this case, shapes of the plurality of through holes 70H may be projected to the display panel 10. In an embodiment, the size 70Hd of the through hole 70H is less than about 0.5 mm, such that the projection of the shapes of the plurality of through holes 70H to the display panel 10 may be prevented or reduced.

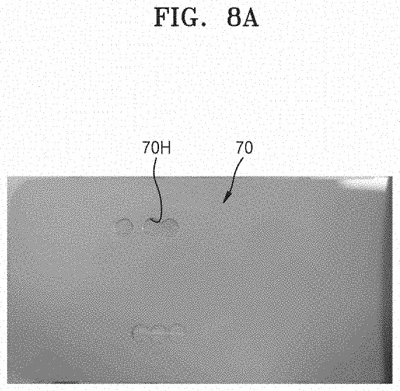

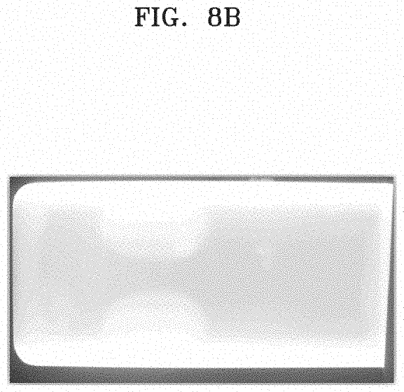

FIG. 8A is a diagram of the metal plate 70 including a through hole 70H. FIG. 8B is a diagram illustrating stains on a display device including the metal plate 70 and a display panel when the display device operates for a long period of time in a high-temperature and high-humidity state.

Referring to FIGS. 8A and 8B, the display device may operate for a long period of time in the high-temperature and high-humidity state. The high temperature may be, for example, about 60° C. The high humidity may be, for example, about 95%. The long period of time may be, for example, about 100 hours. When the display device operates under the above conditions, the result may be similar when the display device operates at a room temperature for a long period of time.

The moisture may permeate from the edges of the metal plate 70, and thus, stains may be formed. In an embodiment where the metal plate 70 includes the through hole 70H as illustrated in FIG. 8A, the moisture may permeate from the through hole 70H. Therefore, an area of the display device, which corresponds to the periphery of an area including the through hole 70H, may have brightness similar to that of an area of the display device, which corresponds to the edge of the metal plate 70. Therefore, in such an embodiment where the metal plate 70 includes the through hole 70H, stains may be reduced or prevented even though the display device operates in a high-temperature and high-humidity environment. In such an embodiment, stains may be reduced or prevented even though the display device operates for a long period of time. In such an embodiment, the display device may display an image without stains even though the display device is used for a long period of time.

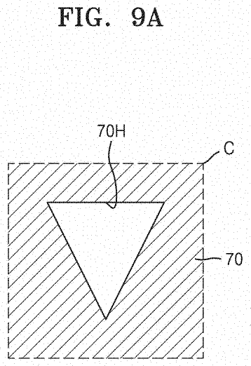

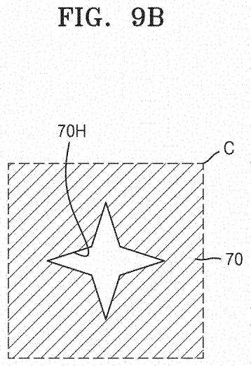

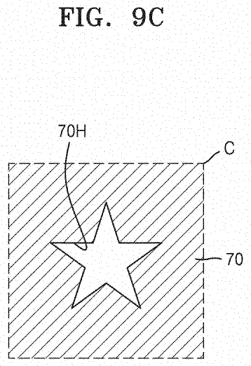

FIGS. 9A to 9C are diagrams of an enlarged region C of the metal plate 70 of FIG. 6, according to various embodiments.

Referring to FIGS. 9A to 9C, an embodiment of the metal plate 70 may include the through hole 70H, that is, the through hole 70H is defined through the metal plate 70. In an embodiment, the metal plate 70 may include the plurality of through holes 70H. A planar shape of the through hole 70H may be one of a circle or a polygon. In an embodiment, for example, the planar shape of the through hole 70H may be a polygon. Referring to FIG. 9A, in an embodiment, the planar shape of the through hole 70H may be a triangle. Referring to FIG. 9B, in an alternative embodiment, the planar shape of the through hole 70H may be a cross. Referring to FIG. 9C, in another alternative embodiment, the planar shape of the through hole 70H may be a star. However, the shape of the through hole 70H is not limited thereto. In another alternative embodiment, the shape of the through hole 70H may be a clover. In embodiments of the invention, as described, the through hole 70H may have various planar shapes.

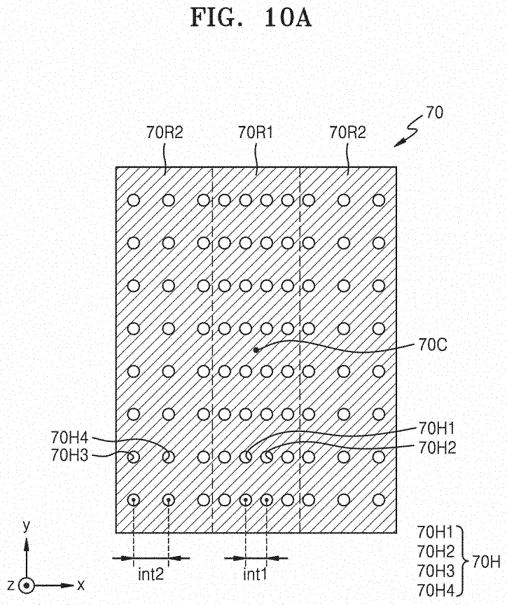

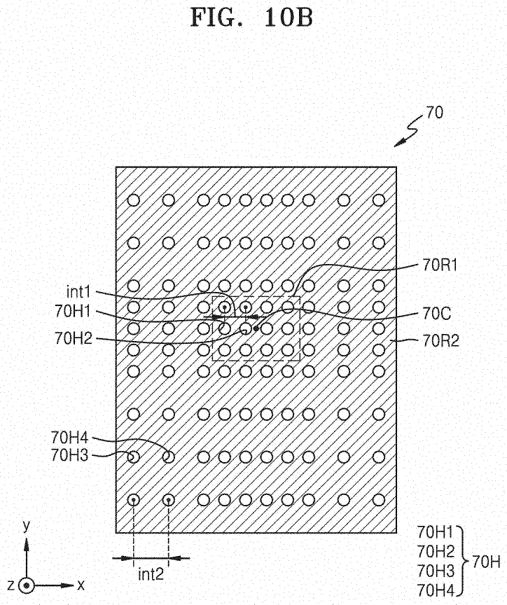

FIGS. 10A and 10B are schematic plan views of the metal plate 70 according to various embodiments. The same reference symbols in FIGS. 10A and 10B denote the same element as those in FIG. 6, and thus, any repetitive detailed descriptions thereof will be omitted.

Referring to FIGS. 10A and 10B, an embodiment of the metal plate 70 may include the plurality of through holes 70H, that is, the plurality of through holes 70H may be defined through the metal plate 70. The plurality of through holes 70H may extend through the metal plate 70. The metal plate 70 may include a first area 70R1 and a second area 70R2. The first area 70R1 may be adjacent to the second area 70R2.

The plurality of through holes 70H may include a first through hole 70H1, a second through hole 70H2, a third through hole 70H3, and a fourth through hole 70H4. The first through hole 70H1 and the second through hole 70H2 may be arranged in the first area 70R1. The first through hole 70H1 and the second through hole 70H2 may be adjacent to each other in the first area 70R1. The first through hole 70H1 and the second through hole 70H2 may be spaced apart from each other at a first interval int1 in the first area 70R1. The first interval int1 may be a distance between the center of the first through hole 70H1 and the center of the second through hole 70H2. The first through hole 70H1 and the second through hole 70H2 may each be provided in plural in the first area 70R1.

The third through hole 70H3 and the fourth through hole 70H4 may be arranged in the second area 70R2. The third through hole 70H3 and the fourth through hole 70H4 may be adjacent to each other in the second area 70R2. The third through hole 70H3 and the fourth through hole 70H4 may be spaced apart from each other at a second interval int2 in the second area 70R2. The second interval int2 may be a distance between the center of the third through hole 70H3 and the center of the fourth through hole 70H4. The third through hole 70H3 and the fourth through hole 70H4 may each be provided in plural in the second area 70R2.

The first interval int1 may be different from the second interval int2. In an embodiment, the first area 70R1 may overlap the center 70C of the metal plate 70. The center 70C of the metal plate 70 may be the center of the metal plate 70 on a plan view. The second area 70R2 may be outside the first area 70R1. In an embodiment, the second area 70R2 may be adjacent to the edge of the metal plate 70. The first interval int1 may be less than the second interval int2. Alternatively, the number of through holes 70H per unit area in the first area 70R1 may be greater than the number of through holes 70H per unit area in the second area 70R2.

The moisture permeation through the plurality of through holes 70H in the first area 70R1 may be greater than the moisture permeation through the plurality of through holes 70H in the second area 70R2. However, the second area 70R2 may be adjacent to the edge of the metal plate 70, and the moisture may permeate from the edge of the metal plate 70. Therefore, in such an embodiment where the first interval int1 is less than the second interval int2, the moisture may evenly permeate into the entire metal plate 70, and the display device may display an image without stains.

The second area 70R2 may surround at least a portion of the first area 70R1. In an embodiment, for example, as illustrated in FIG. 10A, the second area 70R2 may surround only part of the first area 70R1. In such an embodiment, the second area 70R2 may be provided in plural, and the first area 70R1 may be between the plurality of second areas 70R2. FIG. 10A illustrates an embodiment where the first area 70R1 and the second areas 70R2 are arranged side by side in the first direction (e.g., the x direction or the −x direction), but not being limited thereto. In an alternative embodiment, the first area 70R1 and the second areas 70R2 may be arranged side by side in the second direction (e.g., the y direction or the −y direction).

Referring to FIG. 10B, the second area 70R2 may entirely surround the first area 70R1. FIG. 10B illustrates an embodiment where the metal plate 70 only includes the first area 70R1 and the second area 70R2, but not being limited thereto. In an alternative embodiment, the metal plate 70 may further include a third area. The third area may entirely surround the second area 70R2. In such an embodiment, the number of through holes 70H per unit area in the first area 70R1 may be greater than the number of through holes 70H per unit area in the second area 70R2. The number of through holes 70H per unit area in the second area 70R2 may be greater than the number of through holes 70H per unit area in the third area. In such an embodiment, the number of through holes 70H per unit area may gradually decrease in a direction from the center 70C of the metal plate 70 to the edge of the metal plate 70.

In embodiments of the invention, as described above, a display device may include a metal plate including a plurality of through holes. Therefore, the display device may display an image without stains despite the permeation of moisture into the metal plate, and a user may view an image without stains even though the user may use the display device for a long period of time.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel; and
a metal plate disposed under the display panel, wherein the metal plate comprises a first area, and a second area which is adjacent to the first area, and a plurality of through holes is defined through the metal plate,
wherein the plurality of through holes comprise a first through hole and a second through hole, which are spaced apart from each other at a first interval in the first area, and a third through hole and a fourth through hole, which are spaced apart from each other at a second interval in the second area, and
the first interval is different from the second interval.

2. The display device of claim 1, wherein
the first area overlaps a center of the metal plate, and
the first interval is less than the second interval.

3. The display device of claim 2, wherein the second area surrounds at least a portion of the first area.

4. The display device of claim 3, wherein the second area entirely surrounds the first area.

5. The display device of claim 1, wherein an interval between adjacent through holes from among the plurality of through holes is less than or equal to about 2 mm.

6. The display device of claim 1, wherein a size of one of the plurality of through holes is less than or equal to about 0.5 mm.

7. The display device of claim 1, wherein a planar shape of one of the plurality of through holes is one of a circle and a polygon.

8. The display device of claim 1, wherein the display panel comprises:
a substrate comprising a display area;
a pixel circuit layer disposed on the substrate, wherein the pixel circuit layer comprises a pixel circuit overlapping the display area; and
a display element layer disposed on the pixel circuit layer, wherein the display element layer comprises a display element,
wherein the pixel circuit comprises a driving thin film transistor and a switching thin film transistor, and
the plurality of through holes overlap the display area.

9. The display device of claim 1, further comprising:
an adhesive layer disposed between the display panel and the metal plate,
wherein a plurality of openings overlapping the plurality of through holes is defined through the adhesive layer.

10. The display device of claim 9, further comprising:
a protective layer disposed between the display panel and the adhesive layer and overlapping the plurality of through holes; and
a graphite sheet disposed under the metal plate and overlapping the plurality of through holes.

11. A display device comprising:
a display panel;
an adhesive layer disposed under the display panel, a plurality of openings is defined through the adhesive layer;
a metal plate disposed under the adhesive layer, wherein a plurality of through holes overlapping the plurality of openings is defined through the metal plate; and
a graphite sheet disposed under the metal plate and overlapping the plurality of through holes.

12. The display device of claim 11, wherein
the metal plate comprises a first area and a second area which is adjacent to the first area,
the plurality of through holes comprise a first hole and a second through hole, which are spaced apart from each other at a first interval in the first area, and a third hole and a fourth through hole, which are spaced apart from each other at a second interval in the second area, and
the first interval is different from the second interval.

13. The display device of claim 12, wherein
the first area overlaps a center of the metal plate, and
the first interval is less than the second interval.

14. The display device of claim 13, wherein the second area surrounds at least a portion of the first area.

15. The display device of claim 14, wherein the second area entirely surrounds the first area.

16. The display device of claim 12, wherein an interval between adjacent through holes from among the plurality of through holes is less than or equal to about 2 mm.

17. The display device of claim 11, wherein a size of one of the plurality of through holes is less than or equal to about 0.5 mm.

18. The display device of claim 11, wherein a planar shape of one of the plurality of through holes is one of a circle and a polygon.

19. The display device of claim 11, wherein the display panel comprises:
a substrate comprising a display area;
a pixel circuit layer disposed on the substrate, wherein the pixel circuit layer comprises a pixel circuit overlapping the display area; and
a display element layer arranged on the pixel circuit layer, wherein the display element layer comprises a display element,
wherein the pixel circuit comprises a driving thin film transistor and a switching thin film transistor, and
the plurality of through holes overlap the display area.

20. The display device of claim 11, further comprising:
a protective layer disposed between the display panel and the adhesive layer and overlapping the plurality of through holes; and
a reflection prevention layer disposed on the display panel.
